(19) United States
(12) Patent Application Publication
(10) Pub. No.: US 2019/0267296 A1
(43) Pub. Date: Aug. 29, 2019

(54) PREVENTING SOLAR CELL STRESS FRACTURES BY CONTROLLING ENCAPSULANT THICKNESS

(71) Applicant: D2Solar LLC, Santa Clara, CA (US)

(72) Inventor: Duncan Harwood, Santa Clara, CA (US)

(21) Appl. No.: 15/905,382

(22) Filed: Feb. 26, 2018

(51) Int. Cl. H01L 21/66; H01L 31/048; H01L 31/05; H01L 31/18

(52) U.S. Cl. CPC H01L 22/26; H01L 31/1876; H01L 31/05; H01L 31/048

(57) ABSTRACT

Solar panel module manufacture with minimal impact on existing manufacturing processes can include: determining a thickness of an encapsulant for laminating at least one solar cell and at least one conductor onto a substrate of the solar panel module in response to a geometry of the solar cell and the conductor; and laminating the solar cell and the conductor onto the substrate according to the determined thickness.

### BACKGROUND

A solar panel module can include an arrangement of solar cells and conductors laminated onto a glass substrate via an encapsulant. Deformation of the glass substrate, e.g., deformations caused by mechanical loading of the solar panel module from snow, ice, wind, etc., can cause stress fractures to form in the solar cells laminated on the glass substrate. Stress fractures in the solar cells of a solar panel module can interrupt electrical current flow, reduce power generation capacity, and, in extreme cases, create a fire hazard.

Prior attempts to mitigate the formation of stress fractures in the solar cells of a solar panel module include employing expensive and elaborate tools and techniques for soldering conductors to solar cells, arrangements for sandwiching conductors and solar cells between two glass substrates, and providing redundant conductors as backup paths around stress fractures. Such attempts can significantly increase the cost of solar panel module manufacturing, and increase installation costs.

### SUMMARY

In general, in one aspect, the invention relates to a solar panel module with controlled encapsulant thickness. A solar panel module according to the invention can include an encapsulant for laminating at least one solar cell and at least one conductor onto a substrate of the solar panel module such that the encapsulant has a thickness that is selected in response to a geometry of the solar cell and the conductor for a given solar panel design.

In general, in another aspect, the invention relates to a method for manufacturing a solar panel module with controlled encapsulant thickness. The method can include: determining a thickness of an encapsulant for laminating at least one solar cell and at least one conductor onto a substrate of a solar panel module in response to a geometry of the solar cell and the conductor; and laminating the solar cell and the conductor onto the substrate according to the determined thickness.

Other aspects of the invention will be apparent from the following description and the appended claims.

### BRIEF DESCRIPTION OF THE DRAWINGS

Embodiments of the present invention are illustrated by way of example, and not by way of limitation, in the figures of the accompanying drawings and in which like reference numerals refer to similar elements.

FIG. 1 is a cross-sectional view of a solar panel module having an encapsulant with a thickness selected in response to a geometry of a conductor and a solar cell in one or more embodiments.

FIG. 2 is a cross-sectional view of a solar panel module having an encapsulant with a thickness selected in response to a geometry of a ribbon conductor and a set of solar cells in one or more embodiments.

FIG. 3 illustrates a method for manufacturing a solar panel module with controlled encapsulant thickness in one or more embodiments.

### DETAILED DESCRIPTION

Reference will now be made in detail to the various embodiments of the present disclosure, examples of which are illustrated in the accompanying drawings. Like elements in the various figures are denoted by like reference numerals for consistency. While described in conjunction with these embodiments, it will be understood that they are not intended to limit the disclosure to these embodiments. On the contrary, the disclosure is intended to cover alternatives, modifications and equivalents, which may be included within the spirit and scope of the disclosure as defined by the appended claims. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, have not been described in detail so as not to unnecessarily obscure aspects of the present disclosure.

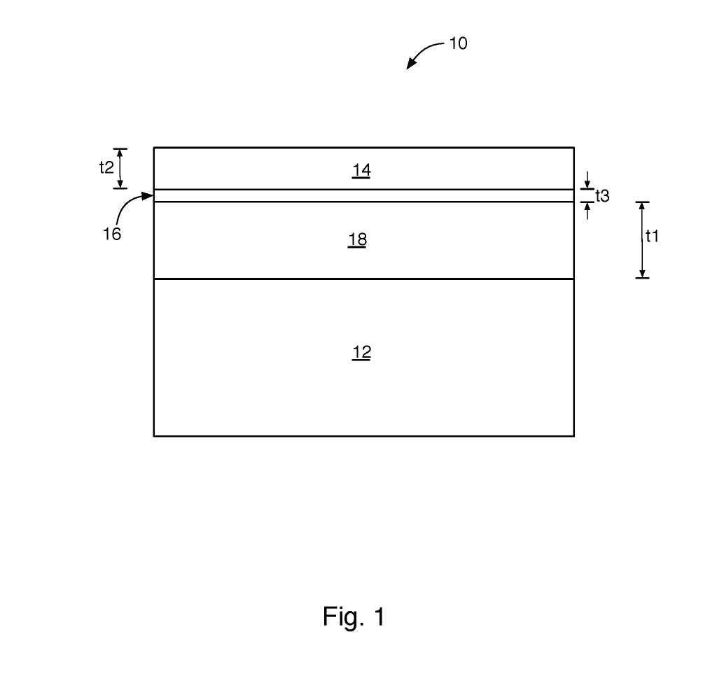

FIG. 1 illustrates a solar panel module 10 with controlled encapsulant thickness in one or more embodiments. The solar panel module 10 includes an encapsulant 18 for laminating a solar cell 14 and a conductor 16 onto a substrate 12 of the solar panel module 10. The encapsulant 18 has a thickness t1 that is selected in response to a geometry of the conductor 16 and the solar cell 14. The geometry of the conductor 16 can include width, thickness, aspect-ratio, roundness in cross-section, etc.

Control of the thickness t1 of the encapsulant 18 can be accomplished in a low-cost manner by repeating existing process steps of solar panel module manufacture. For example, an existing standard step of depositing a 0.5 mm thick layer of encapsulant, e.g., dry films that are thermally laminated, dispensed or deposited, etc., can be repeated to double the thickness of the encapsulant as well as provide an additional safety margin.

The solar cell 14 in one or more embodiments is a silicon cell. The geometry of the solar cell 14 includes a thickness t2 selected according to design criteria for the solar panel module 10. For example, a decrease in the thickness t2 of the solar cell 14 can reduce the cost of the solar panel module 10.

The conductor 16 in one or more embodiments is a copper conductor. The conductor 16 in one or more embodiments is soldered to the solar cell 14. The geometry of the conductor 16 includes a thickness t3 selected according to design criteria for the solar panel module 10. For example, the thickness t3 of the conductor 16 can be adapted to the electrical current generating capacity of the solar cell 14, i.e., a higher current capacity can prompt an increase in the thickness t3 of the conductor 16.

The substrate 12 in one or more embodiments is a glass substrate that can hold any number of solar cells and corresponding conductors. The substrate 12 can be subjected to mechanical stress, deformation, etc., when mechanical loading is applied, e.g., from a snowstorm, or in response to extreme temperature changes due to weather conditions, etc.

The encapsulant 18 can be a layer of a soft adhesive material, e.g., a polymer. The encapsulant 18 in one or more embodiments is an ethylene-vinyl acetate (EVA). The encapsulant 18 in one or more other embodiments is a polyolefin elastomer (POE).

In one or more embodiments, the thickness t1 of the encapsulant 18 is selected in response to the thickness t3 of the conductor 16. For example, if the thickness t1 of the encapsulant 18 is too thin in relation to the thickness t3 of the conductor 16, the conductor 16 may be close enough to the substrate 12 to transmit mechanical stresses from the substrate 12 to the solar cell 14. In such a design case, the thickness t1 of the encapsulant 18 can be increased to maintain a desired amount of cushion for the solar cell 14.

The effects of a thin encapsulant in relation to a thick conductor may not be revealed through standard solar panel certification tests but may be revealed after solar panel module installation and use. The magnitude of this effect can be enhanced by a low temperature pre-condition of a solar panel.

In one or more embodiments, the thickness t1 of the encapsulant 18 is selected in response to the thickness t2 of the solar cell 14. For example, a decrease in the thickness t2 of the solar cell 14 can increase the brittleness of the solar cell 14. An increased brittleness of the solar cell 14 can prompt a need for an increase in the thickness t1 of the encapsulant 18 to prevent mechanical stresses that originate in the substrate 12 from causing stress fractures in the solar cell 14.

In one or more embodiments, the thickness t1 of the encapsulant 18 is selected in response to the thickness t3 of the conductor 16 and the thickness t2 of the solar cell 14. For example, an increase or decrease in the thickness t2 or the thickness t3 or other change in the geometry of the solar cell 14 or the conductor 16 can bring the conductor 16 into closer proximity to the substrate 12 or move the conductor 16 father away from the substrate 12 for a given thickness of the encapsulant 18. In such design cases, the thickness t1 can be increased if needed to maintain a desired amount of cushion for the solar cell 14.

In one or more embodiments, the thickness t1 of the encapsulant 18 is selected in response to a material content of the encapsulant 18. For example, a relatively high stiffness of the encapsulant 18 can facilitate the transmission of mechanical stress from the substrate 12 to the solar cell 14. In such a design case, the thickness t1 of the encapsulant 18 can be increased to maintain a desired amount of cushion for the solar cell 14 despite the stiffness of the encapsulant 18.

The stiffness of the substrate 12 and its thickness can also impact the selection of the thickness t1 of the encapsulant 18. As the thickness of the substrate 12 increases, the amount of strain on the solar cell 14 increases when the substrate 12 is flexed.

If the solar panel module 10 is intended for a colder environment, it may require a greater thickness t1 of the encapsulant 18 because properties of encapsulants are temperature dependent with glass transition temperatures in the −30 C range.

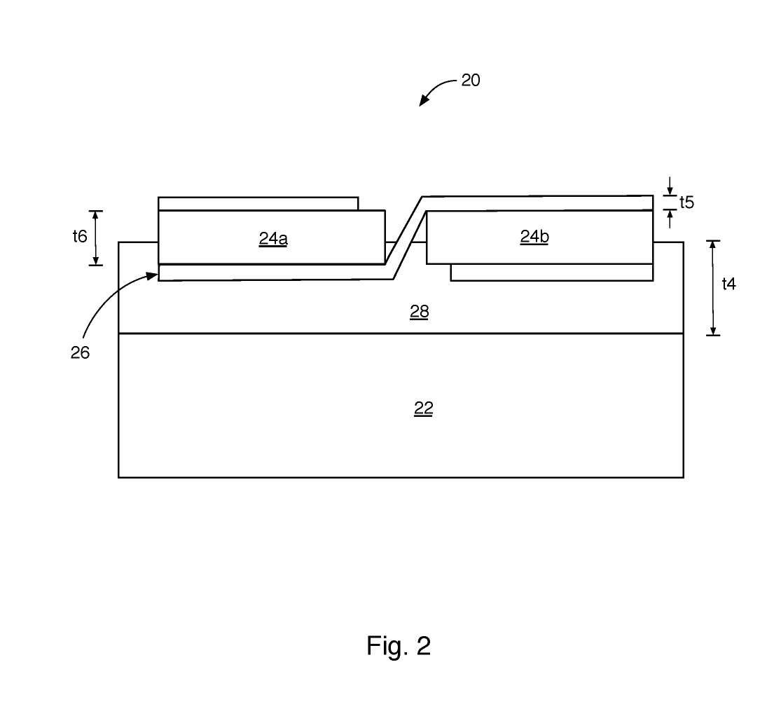

FIG. 2 illustrates a solar panel module 20 having an encapsulant 28 with a thickness t4 selected in response to a geometry of a ribbon conductor 26 for a set of solar cells 24a-b. The thickness t4 of the encapsulant 28 can be selected in response to a thickness t5 of the ribbon conductor 26, or in response to a thickness t6 of the solar cells 24a-b, or in response to a combination of t4 and t5, or in response to a material content of the encapsulant layer 28 as disclosed above.

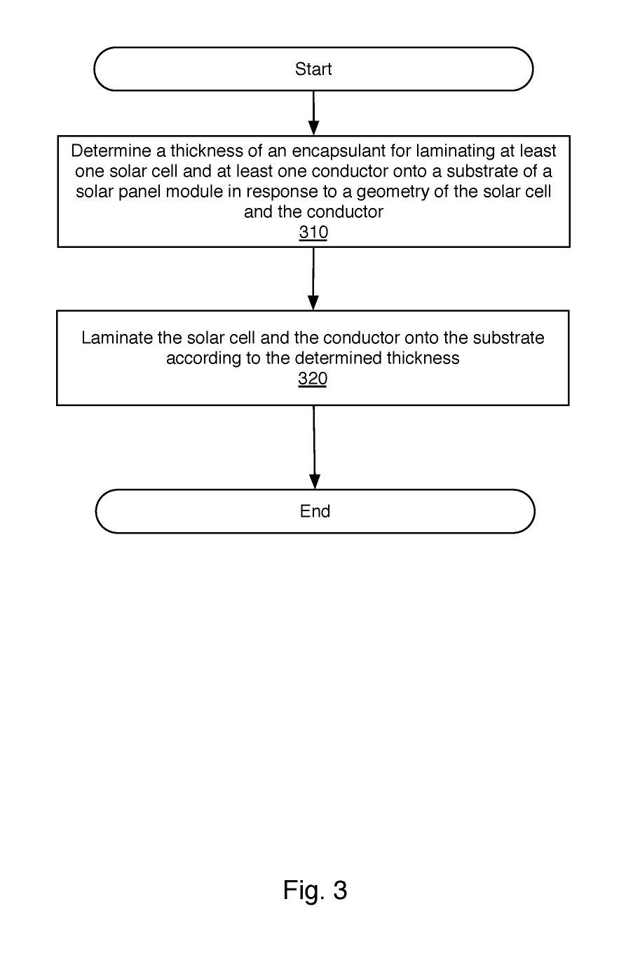

FIG. 3 illustrates a method for manufacturing a solar panel module in one or more embodiments. While the various steps in this flowchart are presented and described sequentially, one of ordinary skill will appreciate that some or all of the steps can be executed in different orders and some or all of the steps can be executed in parallel. Further, in one or more embodiments, one or more of the steps described below can be omitted, repeated, and/or performed in a different order. Accordingly, the specific arrangement of steps shown in FIG. 3 should not be construed as limiting the scope of the invention.

At step 310, a thickness of an encapsulant for laminating at least one solar cell and at least one conductor onto a substrate of a solar panel module is determined in response to a geometry of the solar cell and the conductor. The thickness of the encapsulant can be determined in response to a thickness of the conductor. The thickness of the encapsulant can be determined in response to a thickness of the solar cell. The thickness of the encapsulant can be determined in response to a combination of a thickness of the solar cell and a thickness of the conductor. The thickness of the encapsulant can be determined in response to a stiffness of the encapsulant. The thickness of the encapsulant can be determined by experimentation with different encapsulants and particular geometries of solar cells and conductors.

At step 320, the solar cell and the conductor are laminated onto the substrate according to the thickness determined for the encapsulant. Lamination to a selected thickness may be accomplished using repeated existing lamination steps.

While the foregoing disclosure sets forth various embodiments using specific diagrams, flowcharts, and examples, each diagram component, flowchart step, operation, and/or component described and/or illustrated herein may be implemented, individually and/or collectively, using a range of processes and components.

The process parameters and sequence of steps described and/or illustrated herein are given by way of example only. For example, while the steps illustrated and/or described herein may be shown or discussed in a particular order, these steps do not necessarily need to be performed in the order illustrated or discussed. The various example methods described and/or illustrated herein may also omit one or more of the steps described or illustrated herein or include additional steps in addition to those disclosed.

While the invention has been described with respect to a limited number of embodiments, those skilled in the art, having benefit of this disclosure, will appreciate that other embodiments may be devised which do not depart from the scope of the invention as disclosed herein.

What is claimed is:

1. A solar panel module comprising an encapsulant for laminating at least one solar cell and at least one conductor onto a substrate of the solar panel module such that the encapsulant has a thickness selected in response to a geometry of the solar cell and the conductor.

2. The solar panel module of claim 1, wherein the thickness of the encapsulant is selected in response to a thickness of the conductor.

3. The solar panel module of claim 1, wherein the thickness of the encapsulant is selected in response to a thickness of the solar cell.

4. The solar panel module of claim 1, wherein the thickness of the encapsulant is selected in response to a thickness of the conductor and a thickness of the solar cell.

5. The solar panel module of claim 1, wherein the thickness of the encapsulant is selected in response to a material content of the encapsulant.

6. The solar panel module of claim 1, wherein the solar cell and the conductor are laminated onto the substrate by repeating an existing lamination step for the encapsulant.

7. A method for manufacturing a solar panel module, comprising:
determining a thickness of an encapsulant for laminating at least one solar cell and at least one conductor onto a substrate of the solar panel module in response to a geometry of the solar cell and the conductor; and
laminating the solar cell and the conductor onto the substrate according to the thickness.

8. The method of claim 7, wherein determining a thickness of an encapsulant comprises determining the thickness of the encapsulant in response to a thickness of the conductor.

9. The method of claim 7, wherein determining a thickness of an encapsulant comprises determining the thickness of the encapsulant in response to a thickness of the solar cell.

10. The method of claim 7, wherein determining a thickness of an encapsulant comprises determining the thickness of the encapsulant in response to a thickness of the conductor and a thickness of the solar cell.

11. The method of claim 7, wherein determining a thickness of an encapsulant comprises determining the thickness of the encapsulant in response to a material content of the encapsulant.

12. The method of claim 7, wherein laminating comprises repeating an existing lamination step for forming the encapsulant.
